(19) United States
(12) Patent Application Publication
(10) Pub. No.: US 2009/0159004 A1
(43) Pub. Date: Jun. 25, 2009

(54) VERTICAL CHEMICAL VAPOR DEPOSITION APPARATUS HAVING NOZZLE FOR SPRAYING REACTION GAS TOWARD WAFERS

(75) Inventor: Takahiro YOSHIOKA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Chuo-ku, Tokyo (JP)

(21) Appl. No.: 12/335,767

(22) Filed: Dec. 16, 2008

(30) Foreign Application Priority Data
Dec. 20, 2007 (JP) 2007-328596

(51) Int. Cl. C23C 16/54

(52) U.S. Cl. 118/715

(57) ABSTRACT

A vertical chemical vapor deposition apparatus includes a reaction chamber; and a reaction gas supply nozzle for supplying a reaction gas to the reaction chamber. The reaction gas supply nozzle is positioned adjacent to a side wall surface of the reaction chamber. An expanded surface, which protrudes toward the outside of the reaction chamber, is formed in a part of the side wall surface so that the expanded surface is distant from the reaction gas supply nozzle, where the part is adjacent to the reaction gas supply nozzle. The reaction gas supply nozzle sprays the reaction gas toward a center part of the reaction chamber.

### BACKGROUND OF THE INVENTION

1. Field of the Invention

The present invention relates to a vertical chemical vapor deposition apparatus, and in particular, relates to a technique for preventing generation of particles in the vicinity of a reaction gas supply nozzle.

Priority is claimed on Japanese Patent Application No. 2007-328596, filed Dec. 20, 2007, the contents of which are incorporated herein by reference.

2. Description of Related Art

A vertical chemical vapor deposition apparatus disclosed in Patent Document 1 (Japanese Unexamined Patent Application, First Publication No. H8-199359) is known, and the apparatus generally consists of a vertical reaction chamber for containing a plurality of stacked semiconductor wafers, and a reaction gas supply pipe for supplying a reaction gas to the reaction chamber.

The reaction chamber has an inner tube and an outer tube for surrounding the inner tube, and the semiconductor wafers are contained in the inner tube. A reaction gas supply pipe is arranged along the inner wall surface of the inner tube.

In addition, a reaction gas supply nozzle is provided in the middle of the reaction gas supply pipe, and another reaction gas supply nozzle is provided at the head of the reaction gas supply pipe. A buffer nozzle, which communicates with the reaction gas supply pipe, is attached to each reaction gas supply pipe. Each buffer nozzle has a long hole from which the reaction gas is discharged. In order to discharge the reaction gas, the long hole is provided on the upper surface of the buffer nozzle, and faces upward.

In the reaction gas supply pipe disclosed in Patent Document 1, part of the reaction gas discharged through the long hole is directly sprayed on the inner wall surface of the inner tube. The present inventor has recognized that as the inner tube has a relatively high temperature by means of a heating device (not shown), the reaction gas sprayed on the inner tube is subjected to thermal decomposition, which may produce a doped silicon film on the inner wall surface of the inner tube. In this case, the present inventor has also recognized that if the dopant is a p-type, the dopant concentration of the doped silicon film (deposited on the inner wall surface of the inner tube) may be higher than that of a silicon film which should be formed on a target semiconductor wafer. A doped silicon film, which includes a P-type dopant at a high concentration, has low adhesion properties for a base material, and thus it tends to be detached from the inner wall surface of the inner tube. The detached doped silicon film may produce particles.

### SUMMARY

The present invention seeks to solve one or more of the above problems, or to improve upon those problems at least in part.

In one embodiment, there is provided a vertical chemical vapor deposition apparatus that includes a reaction chamber; and a reaction gas supply nozzle for supplying a reaction gas to the reaction chamber, wherein (i) the reaction gas supply nozzle is positioned adjacent to a side wall surface of the reaction chamber; (ii) an expanded surface, which protrudes toward the outside of the reaction chamber, is formed in a part of the side wall surface so that the expanded surface is distant from the reaction gas supply nozzle, where the part is adjacent to the reaction gas supply nozzle; and (iii) the reaction gas supply nozzle sprays the reaction gas toward a center part of the reaction chamber.

In accordance with the above vertical chemical vapor deposition apparatus, as the expanded surface is provided in the part (of the side wall surface) adjacent to the reaction gas supply nozzle, the reaction gas supply nozzle is distant from the side wall surface of the reaction chamber. In addition, as the reaction gas supply nozzle sprays the reaction gas toward a center part of the reaction chamber, the reaction gas is not directly sprayed on the side wall surface of the reaction chamber. Therefore, no chemical vapor deposited film is formed on the side wall surface of the reaction chamber, thereby preventing generation of particles due to detachment of the chemical vapor deposited film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic sectional view showing the structure of a vertical chemical vapor deposition apparatus according to a first embodiment of the present invention;

FIG. 2 is a perspective view showing an inner tube provided in the vertical chemical vapor deposition apparatus in FIG. 1;

FIGS. 3A to 3D are perspective views, each of which shows a main part of a reaction gas supply pipe provided in the vertical chemical vapor deposition apparatus in FIG. 1; and

FIGS. 4A and 4B are schematic sectional views used for explaining the operation of the vertical chemical vapor deposition apparatus, wherein FIG. 4A is for the operation of a conventional vertical chemical vapor deposition apparatus, and FIG. 4B is for the operation of a vertical chemical vapor deposition apparatus in accordance with the present invention.

### DETAILED DESCRIPTION OF PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

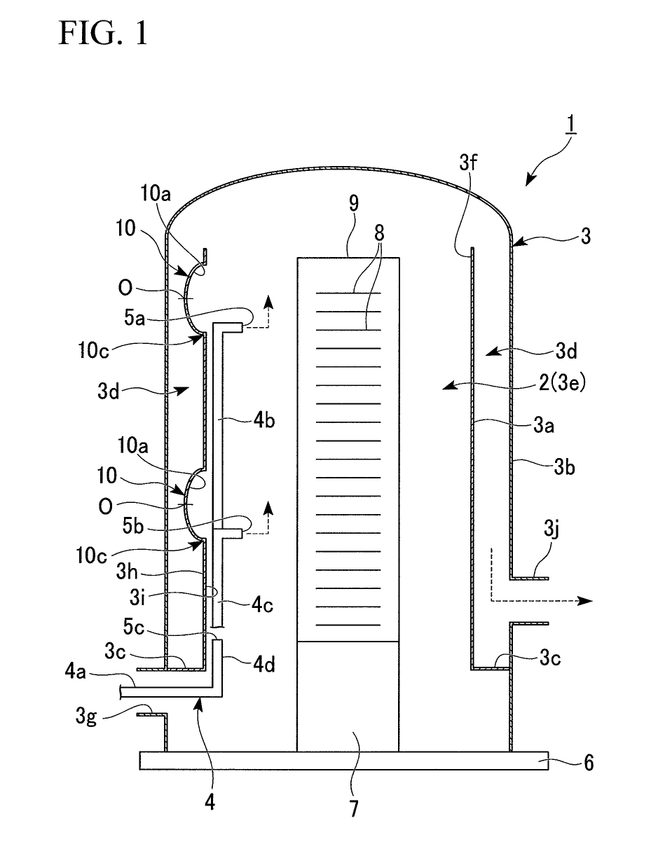

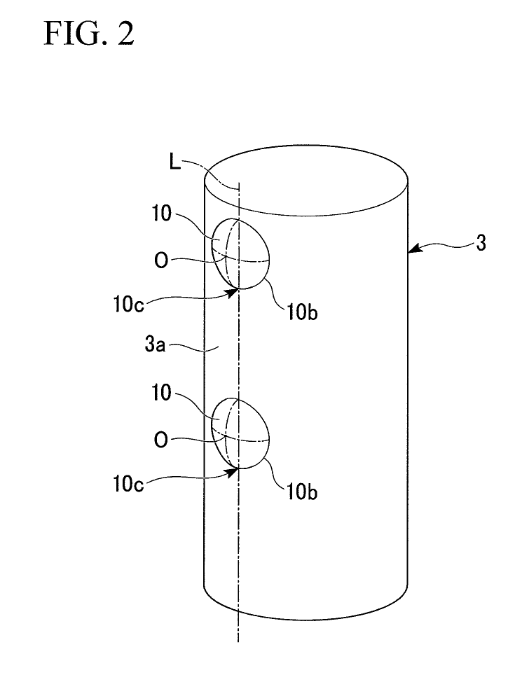

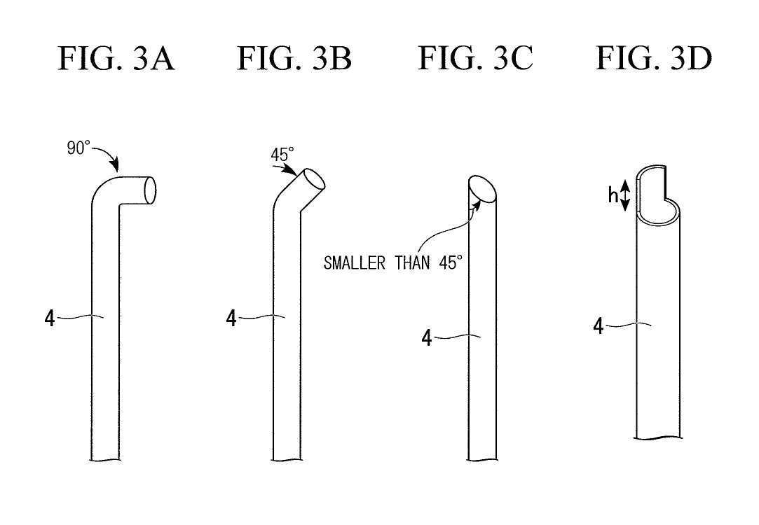

FIG. 1 is a schematic sectional view showing the structure of a vertical chemical vapor deposition apparatus according to a first embodiment of the present invention; FIG. 2 is a perspective view showing an inner tube provided in the vertical chemical vapor deposition apparatus in FIG. 1; and FIGS. 3A to 3D are perspective views, each of which shows a main part of a reaction gas supply pipe provided in the vertical chemical vapor deposition apparatus in FIG. 1. These figures are provided for explaining the structure of the vertical chemical vapor deposition apparatus, and the size, thickness, or dimensions of each shown part may not coincide with dimensional relationships of a corresponding actual vertical chemical vapor deposition apparatus.

Referring now to FIG. 1, a vertical chemical vapor deposition apparatus 1 according to the first embodiment of the present invention may function as a low-pressure chemical vapor deposition apparatus (LPCVD apparatus). However, the present invention is not limited to this, and may be applied to a vertical chemical vapor deposition apparatus in which a reaction gas is supplied to a reaction chamber via a nozzle.

As shown in FIG. 1, the vertical chemical vapor deposition apparatus 1 of the present embodiment generally includes a chamber 3 for forming a reaction chamber 2; a reaction gas supply pipe 4 for supplying a reaction gas to the reaction chamber 2; and reaction gas supply nozzles 5a to 5c, which are respectively provided at the heads of branch pipes 4b to 4d of the reaction gas supply pipe 4.

The chamber 3 is disposed at the center of the upper surface of a loader mechanism 6 having a plate shape. A cap 7 made of silica glass is arranged on the loader mechanism 6. A wafer board 9 is disposed on the cap 7, and contains a plurality of wafers 8 (i.e., semiconductor substrates) which are stacked in a manner such that a specific distance is provided between every two adjacent wafers.

Generally, the chamber 3 consists of (i) an inner tube 3a which is disposed on the loader mechanism 6 and made of a silica glass, and has a hollow cylindrical shape; and (ii) an outer tube 3b which is installed from the upper side of the inner tube 3a so as to cover the inner tube 3a, is made of a silica glass, and has a hollow cylindrical shape having a bottom. The inner tube 3a has a flange part 3c at the lower end thereof. The flange part 3c contacts and is thus joined to the inner wall surface of the outer tube 3b, so that the inner tube 3a and the outer tube 3b are integrated.

Between the inner tube 3a and the outer tube 3b, a gas passage 3d is provided so as to surround the inner tube 3a. In addition, a hollow part 3e of the inner tube 3a functions as the reaction chamber 2, so that the wafers 8 are arranged in the hollow part 3e. An opening 3f is provided on the upper side of the inner tube 3a. The reaction chamber 2 and the gas passage 3d communicate with each other via the opening 3f.

An installation part 3g for installing the reaction gas supply pipe 4 onto the relevant apparatus is provided on the lower side of the outer tube 3b. The reaction gas supply pipe 4 consists of a main pipe 4a and the three branch pipes 4b to 4d branched from the main pipe 4a. The reaction gas supply pipe 4 installed via the installation part 3g is branched into the three branch pipes 4b to 4d on the middle of the reaction gas supply pipe 4. The branch pipes 4b to 4d are arranged along the inner wall surface 3i of a side wall part 3h which forms the inner tube 3a.

The head of the branch pipe 4b is positioned in the upper part of the inner tube 3a in the height direction thereof, and the reaction gas supply nozzle 5a is provided at the head of the branch pipe 4b. The head of the branch pipe 4c reaches the center of the inner tube 3a in the height direction thereof, and the reaction gas supply nozzle 5b is provided at the head of the branch pipe 4c. The head of the branch pipe 4d is positioned in the lower part of the inner tube 3a in the height direction thereof, and the reaction gas supply nozzle 5c is provided at the head of the branch pipe 4d. In addition, a discharge part 3j is provided at the outer tube 3b, and communicates with the gas passage 3d.

The reaction gas supply pipe 4 may be branched prior to the installation part 3g.

In addition, the chamber 3 has a vacuum exhaust system (not shown) so that the degree of vacuum in the chamber 3 (formed by the inner tube 3a and the outer tube 3b) can be controlled so as to have a desired vacuum pressure.

In accordance with the above structure, the reaction gas supplied through the reaction gas supply pipe 4 is supplied via the reaction gas supply nozzles 5a to 5c to the reaction chamber 2, and is used in a CVD reaction on the semiconductor wafers 8, which are arranged in the reaction chamber 2. Unreacted reaction gas and a decomposed gas, which is generated by the CVD reaction, flow upward in the inner tube 3a, together with a carrier gas. The relevant gases which flow out of the opening 3f of the inner tube 3a are drawn into the gas passage 3d, and are then discharged through the discharge part 3j to the outside of the chamber 3.

Below, the inner tube 3a, the reaction gas supply pipe 4, and the reaction gas supply nozzles 5a to 5c will be explained in detail.

As described above, the reaction gas supply pipe 4 consists of the main pipe 4a and the three branch pipes 4b to 4d branched from the main pipe 4a, and the reaction gas supply nozzles 5a to 5c which are the ends of the branch pipes 4b to 4d are respectively arranged at the upper part, the center, and the lower part of the inner tube 3a in the height direction thereof. Such an arrangement is employed for providing the reaction gas through the reaction gas supply nozzles 5a to 5c to the entire area of the vertical reaction chamber 2. As an example of the lengths of the branch pipes 4b to 4d, the branch pipe 4b is 1125 mm, the branch pipe 4c is 725 mm, and the branch pipe 4d is 25 mm.

As shown in FIG. 1, the reaction gas supply nozzles 5a and 5b are respectively arranged at the upper part and the center of the inner tube 3a. In addition, the reaction gas supply nozzles 5a and 5b, as the heads of the branch pipes 4b and 4c, each have a bent shape (from the length of each branch pipe 4b or 4c) toward the center of the reaction chamber 2 (i.e., toward the wafers 8), so as to spray the reaction gas toward the wafers 8 on the center of the reaction chamber 2. Preferably, the bent angle of the reaction gas supply nozzles 5a and 5b is 45 to 90 degrees with respect to the length direction of each branch pipe 4b or 4c. If the bent angle is smaller than 45°, it is too small and increases the possibility of the reaction gas being sprayed toward the inner wall surface 3i of the side wall part 3h in the inner tube 3a. If the bent angle exceeds 90°, it is too large and the reaction gas is sprayed toward the lower part of the inner tube 3a. In this case, it is difficult to provide the reaction gas to the entire reaction chamber 2.

Additionally, as shown in FIGS. 1 and 2, the side wall part 3h of the inner tube 3a has expanded parts 10 which protrude toward the outer tube 3b. In the present embodiment, two expanded parts 10 are provided at the upper part and the center of the inner tube 3a. Each expanded part 10 is formed by protruding a part of the side wall part 3h toward the outer tube 3b in a manner such that the thickness of the side wall part 3h is substantially maintained.

The inner surface of each expanded part 10 is an expanded surface 10a. Although each expanded surface 10a in FIG. 1 is a concave elliptical surface, it is not limited to it, and may be a concave spherical surface. The expanded surface 10a may have a size corresponding to a spherical surface whose diameter is approximately 40 mm.

More specifically, each expanded part 10 is provided by (i) forming an opening by removing a part of the side wall part 3h in the inner tube 3a, which is made of silica glass and has a hollow cylindrical shape, and (ii) attaching a semi-spherical part, which is made of silica glass and formed by using an independent mold, to the opening by welding. For example, in the case of the inner tube 3a shown in FIGS. 1 and 2, a substantially elliptical opening is formed, and a semi-elliptical part, which is made of silica glass and functions as the expanded part 10, is attached to the opening by welding. In FIG. 2, each contact part 10b between the opening and the corresponding silica-glass part has an elliptical shape when observed from the outer-peripheral and the inner-peripheral side of the inner tube 3a.

Additionally, as shown in FIG. 1, the expanded surfaces 10a are provided at positions which are respectively adjacent to the reaction gas supply nozzles 5a and 5b. That is, the branch parts 4b and 4c are arranged on the inner wall surface 3i of the inner tube 3a along the extension line L (see FIG. 2) which connects the two expanded parts 10, so that the two expanded surfaces 10a are respectively adjacent to the reaction gas supply nozzles 5a and 5b. In addition, the reaction gas supply nozzles 5a and 5b are each positioned lower than the center position O of the corresponding expanded surface 10a, and higher than the lower end position 10c of the contact part 10b which defines the expanded surface 10a. When the expanded surface 10a is a concave semi-spherical surface or a concave semi-elliptical surface, the above center position O of the expanded surface 10a is the peak which protrudes to the outer tube 3b most closely. When the expanded surface 10a has a polygonal shape in a plan view, the above center position O is the center of gravity of the relevant polygon.

When employing the above-described positional relationships between the expanded surfaces 10a and the reaction gas supply nozzles 5a and 5b, the reaction gas supply nozzles 5a and 5b are distant from the corresponding expanded surfaces 10a. The gap between the expanded surfaces 10a and the reaction gas supply nozzles 5a and 5b maybe 20 to 30 mm.

The expanded surface 10a is not limited to the above-described concave spherical surface or concave elliptical surface, and may have any shape, such as a trapezoid, rectangle, or triangle, in sectional view.

On the other hand, as shown in FIG. 1, the head of the reaction gas supply nozzle 5c, which is arranged in the lower part of the inner tube 3a in the height direction thereof, is not bent away from the direction along the length of the branch pipe 4d, so that the reaction gas is sprayed in the direction along the length of the branch pipe 4d. Additionally, in the inner tube 3a, no expanded part is provided in the area adjacent to the reaction gas supply nozzle 5c. This is because the cap 7, on which the wafer board 9 is disposed, is arranged in the lower part of the inner tube 3a, and thus the corresponding part in the reaction chamber 2 has a relatively low temperature, so that film adhesion to the inner tube 3a due to a decomposition of the reaction gas scarcely occurs.

The reaction gas supply nozzles 5a and 5b are not limited to those shown in FIG. 1, and may have any form by which the reaction gas can be sprayed toward the center of the reaction chamber 2. For example, not only a reaction gas supply nozzle formed by bending the head part of the reaction gas supply pipe 4 (i.e., branch pipe) by 90° (see FIG. 3A) or 45° (see FIG. 3B), but also a reaction gas supply nozzle formed by cutting the head of the reaction gas supply pipe 4 (i.e., branch pipe) at an angle of 45° or smaller (see FIG. 3C) or by cutting a half of the head of the reaction gas supply pipe 4 (see FIG. 3D), may be used. In FIG. 3D, in the head of the reaction gas supply pipe 4, the half toward the center of the reaction chamber is cut away while the half toward the inner tube remains. The height h of the cut part may be 5 cm, but it is not limited to this.

Next, an example of the relevant thin film formation will be explained. As a thin film formed on the surface of each wafer 8, a phosphorus-doped polysilicon film is formed. In this case, the reaction chamber 2 has a pressure of 0.4 Torr, and the wafers 8 are heated to, for example, approximately 580° C. The reaction gas consists of SiH₄, PH₃, and N₂ (carrier gas). The amount of supplied reaction gas is approximately 1.5 L per minute.

The reaction gas supplied through the reaction gas supply pipe 4 is supplied to the reaction chamber 2 through the reaction gas supply nozzles 5a to 5c, and is used during a CVD reaction performed on the wafers 8 which are arranged in the reaction chamber 2. Unreacted reaction gas and a decomposed gas, which is generated by the CVD reaction, flow upward in the inner tube 3a, and are drawn into the gas passage 3d through the opening 3f. The drawn gases are finally discharged from the discharge part 3j to the outside of the chamber 3.

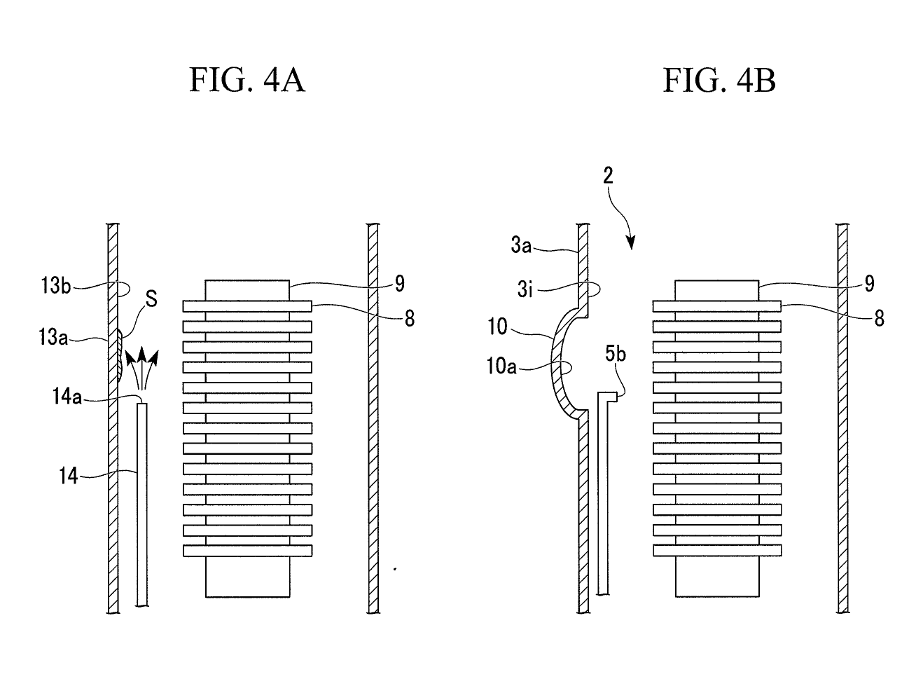

FIGS. 4A and 4B are schematic sectional views used for explaining the operation of the vertical chemical vapor deposition apparatus. FIG. 4A is used for explaining the operation of a conventional vertical chemical vapor deposition apparatus as a comparative example. FIG. 4B is used for explaining the operation of a vertical chemical vapor deposition apparatus in accordance with the present invention.

In the conventional vertical chemical vapor deposition apparatus in FIG. 4A, no expanded part is provided in an inner tube 13a, and the head of a reaction gas supply pipe 14 is not bent so that the reaction gas supply pipe has a straight shape. In the conventional vertical chemical vapor deposition apparatus, although almost of the reaction gas flows upward, part of the reaction gas is sprayed toward an inner wall surface 13b of the inner tube 13a, so that a phosphorus-doped polysilicon film S is formed on the inner wall surface 13b. The formed phosphorus-doped polysilicon film S may have a dopant concentration higher than that of a thin film formed on each wafer 8. As such a phosphorus-doped polysilicon film S has low adhesion properties to a base member made of silica glass or the like, it tends to be detached from the inner tube 13a. The detached doped polysilicon film may produce particles.

In contrast, in the vertical chemical vapor deposition apparatus in accordance with the present invention in FIG. 4B, an expanded surface 10a, which protrudes toward the outside of a reaction chamber 2, is provided at a position (on the inner wall surface 3i of an inner tube 3a) adjacent to a reaction gas supply nozzle 5b, where the inner wall surface 3i functions as the side wall surface of the reaction chamber 2. In addition, the reaction gas supply nozzle 5b and the expanded surface 10a are distant from each other, and the spray direction of the reaction gas supply nozzle 5b is toward the center of the reaction chamber 2 (i.e., toward wafers). Accordingly, no reaction gas is directly sprayed toward the inner wall surface 3i of the inner tube 3a, and thus no phosphorus-doped polysilicon film (i.e., a chemical vapor deposited film) is formed, thereby preventing generation of particles.

It is apparent that the present invention is not limited to the above embodiments, but may be modified and changed without departing from the scope and spirit of the invention.

What is claimed is:

1. A vertical chemical vapor deposition apparatus comprising:
a reaction chamber; and
a reaction gas supply nozzle for supplying a reaction gas to the reaction chamber, wherein:
the reaction gas supply nozzle is positioned adjacent to a side wall surface of the reaction chamber;
an expanded surface, which protrudes toward the outside of the reaction chamber, is formed in a part of the side wall surface so that the expanded surface is distant from the reaction gas supply nozzle, where the part is adjacent to the reaction gas supply nozzle; and
the reaction gas supply nozzle sprays the reaction gas toward a center part of the reaction chamber.

2. The vertical chemical vapor deposition apparatus in accordance with claim 1, wherein:
the reaction chamber has:
an inner tube which has a hollow tubular shape and functions as the side wall surface of the reaction chamber; and
an outer tube which has a hollow tubular shape having a bottom, and covers the inner tube from the upper side thereof, and
an expanded part is formed on a side wall surface of the inner tube, and protrudes toward the outer tube, and the inner surface of the expanded part functions as the expanded surface.

3. The vertical chemical vapor deposition apparatus in accordance with claim 1, wherein the reaction gas supply nozzle is arranged at a position lower than the center position of the expanded surface and higher than the lower end of the expanded surface.

4. The vertical chemical vapor deposition apparatus in accordance with claim 1, wherein wafers are arranged in the center part of the reaction chamber, to which the reaction gas is sprayed.

5. The vertical chemical vapor deposition apparatus in accordance with claim 1, wherein the inner tube and the outer tube each have a hollow cylindrical shape.

6. The vertical chemical vapor deposition apparatus in accordance with claim 1, wherein the expanded surface has a shape selected from the group consisting of a semi-spherical surface, a semi-elliptical surface, a trapezoidal shape in sectional view, a rectangular shape in sectional view, and a triangular shape in sectional view.
